(19) United States
(12) Patent Application Publication
(10) Pub. No.: US 2023/0402533 A1
(43) Pub. Date: Dec. 14, 2023

(54) SEMICONDUCTOR DEVICE

(71) Applicant: FUJI ELECTRIC CO., LTD., Kawasaki-shi (JP)

(72) Inventors: Tomonori MIZUSHIMA, Matsumoto-city (JP); Tatsuya NAITO, Matsumoto-city (JP)

(21) Appl. No.: 18/306,250

(22) Filed: Apr. 25, 2023

(30) Foreign Application Priority Data
Jun. 8, 2022 (JP) 2022-092892

(51) Int. Cl. H01L 29/739; H01L 29/861; H01L 29/10

(52) U.S. Cl. CPC H01L 29/7397; H01L 29/8613; H01L 29/1095

(57) ABSTRACT

There is provided a semiconductor device in which the transistor portion has a first transistor region provided with the emitter region, the contact region, and the first base region; a second transistor region which is provided with the emitter region and the contact region and which is provided between the first transistor region and the diode portion; and a boundary region which includes the second base region and which is provided between the second transistor region and the diode portion, and at a front surface of the semiconductor substrate, an area of the contact region in the second transistor region is smaller than an area of the contact region in the first transistor region.

The contents of the following Japanese patent application(s) are incorporated herein by reference:
NO. 2022-092892 filed in JP on Jun. 8, 2022

### BACKGROUND

### 1. Technical Field

The present invention relates to a semiconductor device.

### 2. Related Art

Patent Document 1 discloses that a carrier injection suppression layer is provided in an insulated gate bipolar transistor region to suppress holes flowing into a diode region and enhance a breakdown resistance during a recovery operation. Patent Document 2 discloses that a carrier suppression region exposed from a first surface of a semiconductor substrate is formed, and a first electrode has a Schottky barrier junction with the carrier suppression region.

### PRIOR ART DOCUMENT

### [Patent Document]

[Patent Document 1] Japanese Patent Application Publication No. 2021-158199
[Patent Document 2] Japanese Patent Application Publication No. 2021-144998

### BRIEF DESCRIPTION OF THE DRAWINGS

FIG. 1 shows an example of a top plan view of a semiconductor device 100 according to example embodiment 1.

FIG. 2 shows an example of an enlarged view of a region A in FIG. 1.

FIG. 3 is a view showing an example of a cross section a-a′ in FIG. 2.

FIG. 4 shows an example of a bottom plan view of the semiconductor device 100.

FIG. 5 shows another example of the bottom plan view of the semiconductor device 100.

FIG. 6 shows an example of an enlarged view of an upper surface of a semiconductor device 1100 according to a comparison example.

FIG. 7 is a view showing an example of a cross section a-a′ in FIG. 6.

FIG. 8 shows an example of a top plan view of a semiconductor device 200 according to example embodiment 2.

FIG. 9 shows an example of a top plan view of a semiconductor device 300 according to example embodiment 3.

FIG. 10 is a graph showing a temporal change in collector current Ic at a time of a reverse recovery.

### DESCRIPTION OF EXEMPLARY EMBODIMENTS

Hereinafter, embodiments of the present invention will be described, but the embodiments do not limit the invention according to the claims. In addition, not all of the combinations of features described in the embodiments are essential to the solving means of the invention.

In the present specification, one side in a direction parallel to a depth direction of a semiconductor substrate is referred to as an “upper” side, and the other side is referred to as a “lower” side. One surface of two principal surfaces of a substrate, a layer, or another member is referred to as an upper surface, and the other surface is referred to as a lower surface. “Upper”, “lower”, “front”, and “back” directions are not limited to a direction of gravity, or a direction of an attachment to a substrate or the like when a semiconductor device is mounted.

In the present specification, technical matters may be described by using orthogonal coordinate axes of an X axis, a Y axis, and a Z axis. In the present specification, a plane parallel to a front surface of the semiconductor substrate is referred to as an XY plane, and the depth direction of the semiconductor substrate is referred to as the Z axis. It should be noted that in the present specification, in a case where the semiconductor substrate is viewed in a Z axis direction, the view is referred to as a top view.

Each example embodiment shows an example in which a first conductivity type is set as an N type, and a second conductivity type is set as a P type; however, the first conductivity type may be the P type, and the second conductivity type may be the N type. In this case, conductivity types of the substrate, the layer, a region, and the like in each example embodiment respectively have opposite polarities.

In the present specification, a character N or P specifying a layer or a region means that electrons or holes are majority carriers, respectively. In addition, each of a symbol “+” and a symbol “−” added to N or P represents a layer or a region of a higher doping concentration and a lower doping concentration than that of a layer or a region without the symbol, and a symbol “++” represents a higher doping concentration than “+” while a symbol “−−” represents a lower doping concentration than “−”.

In the present specification, a doping concentration refers to a concentration of a donor or a dopant that has turned into an acceptor. Accordingly, a unit thereof is /cm³. In the present specification, a difference in concentration (that is, a net doping concentration) between the donor and the acceptor may be set as the doping concentration. In this case, the doping concentration can be measured by an SRP method. In addition, a chemical concentration of the donor and the acceptor may also be set as the doping concentration. In this case, the doping concentration can be measured by a SIMS method. If not particularly limited, any of the above may be used as the doping concentration. If not particularly limited, a peak value of a doping concentration distribution in a doping region may be set as the doping concentration in the doping region.

In addition, in the present specification, a dose amount refers to the number of ions implanted into a wafer per unit area when the ions are implanted. Accordingly, a unit thereof is /cm². It should be noted that a dose amount of a semiconductor region can be set as an integrated concentration obtained by integrating doping concentrations across the semiconductor region in the depth direction. A unit of the integrated concentration is /cm². Accordingly, the dose amount and the integrated concentration may be treated as the same. The integrated concentration may also be set as an integral value up to a half-value width, and in a case of being overlapped by a spectrum of another semiconductor region, the integrated concentration may be derived without an influence of the other semiconductor region.

Therefore, in the present specification, a level of the doping concentration can be read as a level of the dose amount. That is, when the doping concentration of one region is higher than the doping concentration of another region, it can be understood that the dose amount of the one region is higher than the dose amount of the other region.

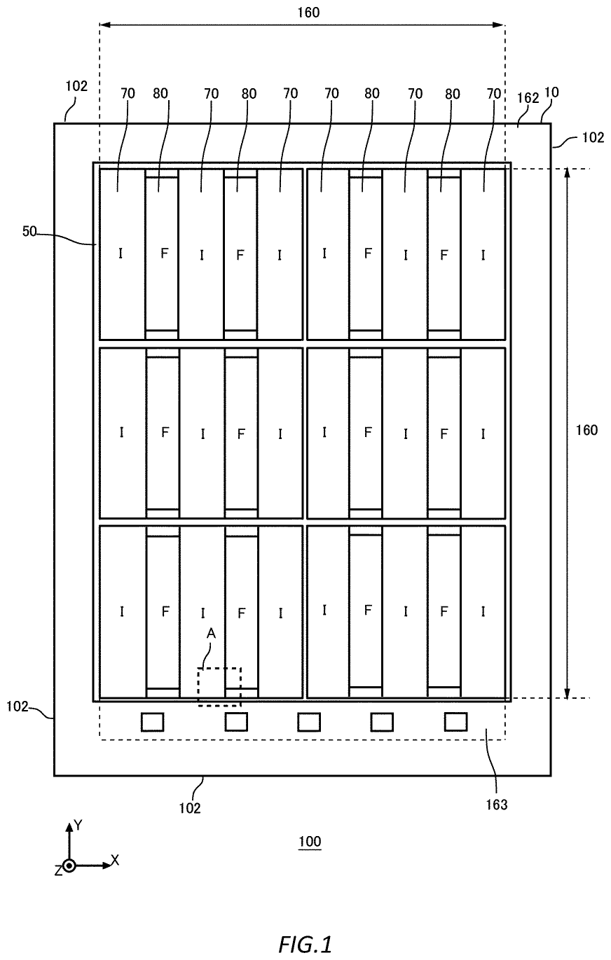

FIG. 1 shows an example of a top plan view of a semiconductor device 100 according to an example embodiment. FIG. 1 shows a position at which each member is projected onto a front surface of a semiconductor substrate 10. FIG. 1 shows merely some members of the semiconductor device 100, and omits illustrations of some members.

The semiconductor device 100 includes the semiconductor substrate 10. The semiconductor substrate 10 has an edge side 102 in the top view. The semiconductor substrate 10 of the present example has two sets of edge sides 102 opposite to each other in the top view. The X axis and the Y axis are parallel to any of the edge sides 102. In the present specification, an array direction of a transistor portion 70 and a diode portion 80, which will be described below, is referred to as the X axis, and an extension direction perpendicular to the array direction in the top view is referred to as the Y axis. In addition, the Z axis is perpendicular to the front surface of the semiconductor substrate 10.

The semiconductor substrate 10 is provided with an active region 160. The active region 160 is a region where a main current flows in the depth direction between the front surface and a back surface of the semiconductor substrate 10, when the semiconductor device 100 is operated. Above the active region 160, an emitter electrode 52 is provided, but is omitted in FIG. 1.

In FIG. 1, the active region 160 is divided by a gate wiring layer 50 which will be described below. The active region 160 of the present example may be divided into two in an X axis direction and three in a Y axis direction. These active regions 160 are electrically connected to each other by the emitter electrode 52 which will be described below. It should be noted that the number of active regions 160 divided by the gate wiring layer 50 may appropriately be changed.

The active region 160 is provided with the transistor portion 70 and the diode portion 80. For example, the semiconductor device 100 is a reverse conducting insulated gate bipolar transistor (RC-IGBT: Reverse Conducting IGBT) in which an insulated gate bipolar transistor (IGBT: Insulated Gate Bipolar Transistor) is provided in the transistor portion 70, and a freewheeling diode (FWD: Free Wheeling Diode) is provided in the diode portion 80. It should be noted that the semiconductor device 100 may be the IGBT or a MOS transistor.

In the present example, the transistor portion 70 and the diode portion 80 are alternately arranged along the array direction (the X axis direction) at the front surface of the semiconductor substrate 10.

In FIG. 1, a region where each of the transistor portions 70 is arranged is indicated by a symbol “|”, and a region where each of the diode portions 80 is arranged is indicated by a symbol F. Each of the transistor portions 70 and the diode portions 80 may have a longitudinal length in the extension direction. In other words, a length of each of the transistor portions 70 in the Y axis direction is greater than a width in the X axis direction. Similarly, a length of each of the diode portions 80 in the Y axis direction is greater than a width in the X axis direction. The extension direction of the transistor portion 70 and the diode portion 80, and a longitudinal direction of each trench portion which will be described below may be the same.

In FIG. 1, an end portion of the transistor portion 70 in the Y axis direction is located to be closer to an outer periphery side of the active region 160 than an end portion of the diode portion in the Y axis direction. In addition, the width of the transistor portion 70 in the X axis direction is greater than the width of the diode portion 80 in the X axis direction.

The diode portion 80 has a cathode region of an N+ type on a back surface side of the semiconductor substrate 10. In the present specification, a region where the cathode region is provided is referred to as the diode portion 80. In other words, the diode portion 80 is a region that overlaps the cathode region in the top view. The back surface of the semiconductor substrate may be provided with a collector region of a P+ type in a region other than the cathode region.

The transistor portion 70 has the collector region of the P+ type on the back surface side of the semiconductor substrate 10. In addition, in the transistor portion 70, an emitter region of the N type, a base region of the P type, and a gate trench portion having a gate conductive portion and a gate dielectric film are arranged at regular intervals, in a front surface side of the semiconductor substrate 10.

The semiconductor device 100 may have one or more pads above the semiconductor substrate 10. As an example, the semiconductor device 100 may include a pad region 163. The pad region 163 may include a pad such as a gate pad, an anode pad and a cathode pad for a temperature sensing diode (not shown), and a current sensing pad for current sensing (not shown). The pad region 163 is arranged between the active region 160 and an edge termination structure portion 162, which will be described below. When the semiconductor device 100 is mounted, each pad may be connected to an external circuit via wiring such as a wire.

The gate wiring layer 50 electrically connects a gate conductive portion 44 provided in the gate trench portion which will be described below, and a gate pad. The gate wiring layer 50 of the present example surrounds the active region 160 in the top view.

In the semiconductor device 100 of the present example, the active region 160 and the pad region 163 adjacent to the active region 160 are surrounded by the edge termination structure portion 162. The edge termination structure portion 162 relaxes an electric field concentration in the front surface side of the semiconductor substrate 10. The edge termination structure portion 162 may include a plurality of guard rings. The guard ring is a region of the P type in contact with the front surface of the semiconductor substrate 10. By a plurality of guard rings being provided, it is possible to extend outward a depletion layer in an upper surface side of the active region 160, and it is possible to improve a withstand voltage of the semiconductor device 100. The edge termination structure portion 162 may further include at least one of a field plate and a RESURF which are annularly provided to surround the active region 160 and the pad region 163.

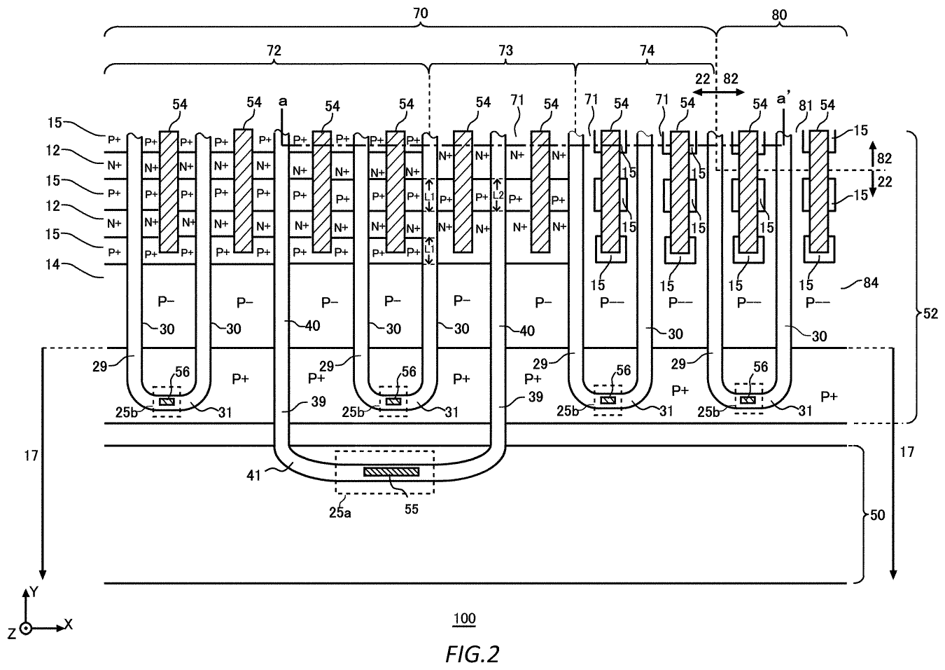

FIG. 2 is an enlarged view which shows an example of a region A in FIG. 1. A region A is a boundary periphery between the transistor portion 70 and the diode portion 80, and the pad region 163, on a negative side in the Y axis direction of the semiconductor device 100, in the top view.

The transistor portion 70 is a region where a collector region 22 provided on the back surface side of the semiconductor substrate 10 is projected onto the front surface of the semiconductor substrate 10. As an example, the collector region 22 of the present example is of the P+ type. The transistor portion 70 includes a transistor such as the IGBT.

The diode portion 80 is a region where a cathode region 82 provided on the back surface side of the semiconductor substrate 10 is projected onto the front surface of the semiconductor substrate 10. As an example, the cathode region 82 of the present example is of the N+ type. The diode portion 80 includes a diode such as the freewheeling diode (FWD: Free Wheel Diode) provided to be adjacent to the transistor portion 70 at the front surface of the semiconductor substrate 10.

The semiconductor substrate 10 may be a silicon substrate, may be a silicon carbide substrate, or may be a nitride semiconductor substrate or the like of gallium nitride or the like. The semiconductor substrate 10 in the present example is a silicon substrate.

The semiconductor device 100 of the present example includes a gate trench portion 40, a dummy trench portion 30, an emitter region 12, a first base region 14, a second base region 84, a contact region 15, and a well region 17, in the front surface side of the semiconductor substrate 10. The semiconductor device 100 of the present example also includes the emitter electrode 52 and the gate wiring layer 50 which are provided above the front surface of the semiconductor substrate 10.

The emitter electrode 52 is provided above the gate trench portion 40, the dummy trench portion 30, the emitter region 12, the first base region 14, the second base region 84, the contact region 15, and the well region 17. In addition, the gate wiring layer 50 is provided above the gate trench portion 40 and the well region 17.

The emitter electrode 52 and the gate wiring layer 50 are formed of a material containing metal. At least a part of a region of the emitter electrode 52 may be formed of aluminum, or an alloy (for example, an aluminum-silicon alloy, an aluminum-silicon-copper alloy, or the like) which contains aluminum as a main component. At least a part of a region of the gate wiring layer 50 may be formed of aluminum, or an alloy (for example, an aluminum-silicon alloy, an aluminum-silicon-copper alloy, or the like) which contains aluminum as a main component. The emitter electrode 52 and the gate wiring layer 50 may have barrier metal formed of titanium, a titanium compound, or the like under a region formed of aluminum and the like. The emitter electrode 52 and the gate wiring layer 50 are provided to be electrically separated from each other.

The emitter electrode 52 and the gate wiring layer 50 are provided above the semiconductor substrate 10 with an interlayer dielectric film 38 interposed therebetween. The interlayer dielectric film 38 is omitted in FIG. 2. A contact hole 54, a contact hole 55, and a contact hole 56 are provided to pass through the interlayer dielectric film 38.

The contact hole 55 connects the gate conductive portion 44 in the gate trench portion 40 in the transistor portion 70, and the gate wiring layer 50. In the contact hole 55, a plug formed of tungsten or the like may be provided via the barrier metal.

The contact hole 56 connects dummy conductive portions 34 in the dummy trench portions 30 which are provided in the transistor portion 70 and the diode portion 80 and which will be described below, and the emitter electrode 52. In the contact hole 56, a plug formed of tungsten or the like may be provided via the barrier metal.

At a connection portion 25a, the gate wiring layer 50 is electrically connected to the semiconductor substrate 10 via the contact hole 55. At a connection portion 25b, the emitter electrode 52 is electrically connected to the semiconductor substrate 10 via the contact hole 56.

In an example, the connection portion 25a is provided in a region including an interior of the contact hole 55, between the gate wiring layer 50 and the gate conductive portion 44. The connection portion 25b is provided in a region including an interior of the contact hole 56, between the emitter electrode 52 and a dummy conductive portion 34.

The connection portions 25a, 25b are formed of a conductive material including metal such as tungsten, and polysilicon doped with impurities, or the like. In addition, the connection portions 25a, 25b may also have the barrier metal of titanium nitride or the like. Here, the connection portion 25 is formed of polysilicon (N+) doped with the impurities of the N type. The connection portions 25a, 25b are provided above the front surface of the semiconductor substrate via a dielectric film such as an oxide film, or the like.

The gate trench portion 40 is arrayed at a predetermined interval along a predetermined array direction (the X axis direction in the present example). The gate trench portion 40 of the present example may have: two extension parts 39 that extend along the extension direction (the Y axis direction in the present example) which is parallel to the front surface of the semiconductor substrate 10 and which is perpendicular to the array direction; and a connection part 41 that connects the two extension parts 39.

It is preferable that at least a part of the connection part 41 is formed in a curved shape. By connecting end portions of the two extension parts 39 of the gate trench portion 40, electric field concentrations at the end portions of the extension parts 39 can be relaxed. At the connection part 41 of the gate trench portion 40, the gate wiring layer 50 may be connected to the gate conductive portion 44.

The dummy trench portion 30 is a trench portion in which the dummy conductive portion 34 is provided to be electrically connected to the emitter electrode 52. The dummy trench portion 30 is arrayed, similarly to the gate trench portion 40, at a predetermined interval along a predetermined array direction (the X axis direction in the present example). The dummy trench portion 30 of the present example may have, similarly to the gate trench portion 40, a U shape at the front surface of the semiconductor substrate 10. That is, the dummy trench portion 30 may have two extension parts 29 that extend along the extension direction, and a connection part 31 that connects the two extension parts 29.

The contact hole 54 of the present example is provided above each region of the emitter region 12 and the contact region 15 in the transistor portion 70. The contact hole 54 is provided above the contact region 15 and the second base region 84 in the diode portion 80. None of the contact holes 54 is provided above the well regions 17 provided at both ends in the Y axis direction. In this way, an interlayer dielectric film is provided with one or more contact holes 54. One or more contact holes 54 may be provided to extend in the extension direction.

A mesa portion 71 and a mesa portion 81 are mesa portions provided adjacent to the trench portion in a plane parallel to the front surface of the semiconductor substrate 10. The mesa portion is a part of the semiconductor substrate 10 interposed between two trench portions adjacent to each other, and may be a part ranging from the front surface of the semiconductor substrate 10 to a depth of a deepest bottom portion of each trench portion. The extension part of each trench portion may be set as one trench portion. That is, a region interposed between two extension parts may be set as the mesa portion.

The mesa portion 71 is provided adjacent to at least one of the dummy trench portion 30 or the gate trench portion 40 in the transistor portion 70.

The mesa portion 81 is provided in a region interposed between the dummy trench portions 30 adjacent to each other in the diode portion 80. The mesa portion 81 of the present example has the second base region 84 at the front surface of the semiconductor substrate 10, and the well region 17 on the negative side in the Y axis direction. The mesa portion 81 may be provided with the contact region 15 at a front surface of the second base region 84.

The transistor portion 70 includes a first transistor region 72, a second transistor region 73 provided between the first transistor region 72 and the diode portion 80, and a boundary region 74 provided between the second transistor region 73 and the diode portion 80.

The first transistor region 72 and the second transistor region 73 have the emitter region 12, the contact region 15, and the first base region 14. The mesa portion 71 of the first transistor region 72 and the second transistor region 73 has the well region 17, the emitter region 12, the first base region 14, and the contact region 15, at the front surface of the semiconductor substrate 10.

The first transistor region 72 and the second transistor region 73 have a structure in which one gate trench portion 40 and two dummy trench portions 30 are repeatedly arrayed. That is, the first transistor region 72 and the second transistor region 73 of the present example have the gate trench portion 40 and the dummy trench portion 30 at a ratio of 1:2. For example, the transistor portion 70 has two extension parts 29 between two extension parts 39.

Note that the ratio of the gate trench portion 40 and the dummy trench portion 30 is not limited to that of the present example. The ratio of the gate trench portion 40 and the dummy trench portion 30 may be 1:1, or may be 2:3. In addition, the transistor portion 70 may be entirely provided with the gate trench portion 40 without being provided with the dummy trench portion 30.

The first base region 14 is a region provided in the front surface side of the semiconductor substrate 10, in the transistor portion 70. The first base region 14 is of a P− type as an example. The first base regions 14 may be provided at both end portions of the mesa portions 71 of the first transistor region 72 and the second transistor region 73, in the Y axis direction, at the front surface of the semiconductor substrate 10. It should be noted that FIG. 2 shows only an end portion of the first base region 14 on the negative side in the Y axis direction.

The second base region 84 is a region provided in the front surface side of the semiconductor substrate 10, in the boundary region 74 and the diode portion 80. The second base region 84 is of a P−− type as an example. The doping concentration of the second base region 84 is lower than the doping concentration of the first base region 14. The second base regions 84 may be provided at both end portions of the mesa portion 71 of the boundary region 74 and the mesa portion 81, in the Y axis direction, at the front surface of the semiconductor substrate 10. It should be noted that FIG. 2 shows only an end portion of the second base region 84 on the negative side in the Y axis direction. Here, in the diode portion 80, the second base region 84 corresponds to an anode layer.

The emitter region 12 is a region which is of the same conductivity type as that of a drift region 18 and which has a doping concentration higher than that of the drift region 18. The emitter region 12 of the present example is of the N+ type as an example. An example of the dopant of the emitter region 12 is arsenic (As). In the first transistor region 72 and the second transistor region 73, the emitter region 12 is provided in contact with the gate trench portion 40. In the first transistor region 72 and the second transistor region 73, the emitter region 12 may be provided to extend in the X axis direction from one trench portion to the other trench portion of two trench portions that interpose the mesa portion 71 therebetween. The emitter region 12 is also provided below the contact hole 54.

In addition, the emitter region 12 may be, or may not be in contact with the dummy trench portion 30. The emitter region 12 of the present example is in contact with the dummy trench portion 30. The emitter region 12 may not be provided in the boundary region 74 and the mesa portion 81.

The contact region 15 is a region which is of the same conductivity type as that of the first base region 14 and which has a doping concentration higher than that of the first base region 14. The contact region 15 of the present example is of the P+ type as an example. The contact region 15 of the present example is provided at a front surface of the mesa portion 71. In the first transistor region 72 and the second transistor region 73, the contact region 15 may be provided to extend in the X axis direction from one trench portion to the other trench portion of two trench portions that interpose the mesa portion 71 therebetween. On the other hand, in the boundary region 74, an end portion of the contact region 15 in the X axis direction is spaced apart from the adjacent trench portion. Furthermore, in the boundary region 74, the contact region 15 is selectively provided in the Y axis direction.

The contact region 15 may be, or may not be in contact with the gate trench portion 40. In addition, the contact region 15 may be, or may not be in contact with the dummy trench portion 30. In the first transistor region 72 and the second transistor region 73, the contact region 15 is in contact with the dummy trench portion 30 and the gate trench portion 40. On the other hand, in the boundary region 74, the contact region 15 is spaced apart from the dummy trench portion 30. The contact region 15 is also provided below the contact hole 54.

In the present example, in the mesa portion 71 of the first transistor region 72 and the second transistor region 73, the emitter region 12 and the contact region 15 are alternately provided in the extension direction (the Y axis direction). In the first transistor region 72 and the second transistor region 73 of the present example, the first base region 14 is not exposed to the front surface of the semiconductor substrate 10.

At the front surface of the semiconductor substrate 10, an area of the contact region 15 in the second transistor region 73 is smaller than an area of the contact region 15 in the first transistor region 72. That is, in the second transistor region 73, a ratio of a length of the emitter region 12 in the Y axis direction to a length of the contact region 15 in the Y axis direction is greater than that in the first transistor region 72.

In the present example, when the length, in the extension direction (the Y axis direction), of one contact region 15 of the first transistor region 72 is set as L1, and the length, in the extension direction (the Y axis direction), of the contact region 15 of the second transistor region 73 that is aligned with the one contact region 15 in the array direction (the X axis direction) is set as L2, L2=L1 or L2=0. That is, in the second transistor region 73, at a position that is aligned with the contact region 15 of the first transistor region 72 in the array direction, the contact region 15 or the emitter region 12 is provided to have the length L2 in the extension direction, which is the same as L1. A width of the second transistor region 73 may be narrower than a width of the boundary region 74 in the array direction (the X axis direction).

When the transistor portion 70 is turned off and the diode portion 80 conducts electrocity, an electron current flows from the cathode region 82 to the second base region 84 which is operated as the anode layer, and a reverse recovery current is generated. When the electron current reaches the second base region 84, a conductivity modulation occurs, and a hole current flows from the anode layer.

At this time, the electron current is also diffused from the cathode region 82 to the first base region 14 of the transistor portion 70. The electron current which is diffused toward the transistor portion 70 promotes a hole injection from the contact region 15 having a doping concentration higher than that of the first base region 14, and increases a hole density in the semiconductor substrate 10, and thus it takes time for a hole to annihilate along with the turn off of the diode portion 80. Therefore, a peak reverse recovery current increases and a reverse recovery loss becomes greater.

In the second transistor region 73 of the present example, an area ratio of the contact region 15 is made to be smaller than that in the first transistor region 72, and thus it is possible to suppress the hole injection and reduce the reverse recovery loss.

The boundary region 74 is a region which is adjacent to the diode portion 80, within the transistor portion 70, and which is not operated as a transistor. The mesa portion 71 of the boundary region 74 has the well region 17, the emitter region 12, the second base region 84, and the contact region 15, at the front surface of the semiconductor substrate 10.

In the diode portion 80 of the present example, the contact region 15 is not in contact with the dummy trench portion 30, and is provided to be interposed between the second base regions 84 in the extension direction (the Y axis direction) and the array direction (the X axis direction). In the diode portion 80, the end portion of the contact region 15 in the X axis direction is spaced apart from the adjacent dummy trench portion 30 in a plan view, and the contact region 15 is selectively provided in the Y axis direction.

Similarly, in the boundary region 74 of the present example, the contact region 15 is not in contact with the dummy trench portion 30, and is provided to be interposed between the second base regions 84 in the extension direction and the array direction. That is, the boundary region 74 is a part of the transistor portion 70, but has a front surface structure similar to that of the diode portion 80.

In this way, by providing the boundary region 74 having the second base region 84 with a low doping concentration on a diode portion 80 side in the transistor portion 70, it is possible to suppress the hole injection and reduce the reverse recovery loss.

The well region 17 is provided to be closer to the front surface side of the semiconductor substrate 10 than the drift region 18 which will be described below. The well region 17 is an example of a well region provided on an edge side of the semiconductor device 100. The well region 17 is of the P+ type as an example. The well region 17 is provided in a predetermined range from an end portion of an active region on a side on which the gate wiring layer 50 is provided. A diffusion depth of the well region 17 may be deeper than depths of the gate trench portion 40 and the dummy trench portion 30. Parts of regions of the gate trench portion 40 and the dummy trench portion 30 on a gate wiring layer 50 side are provided in the well region 17. Bottoms of ends of the gate trench portion 40 and the dummy trench portion 30 in the extension direction may be covered with the well region 17.

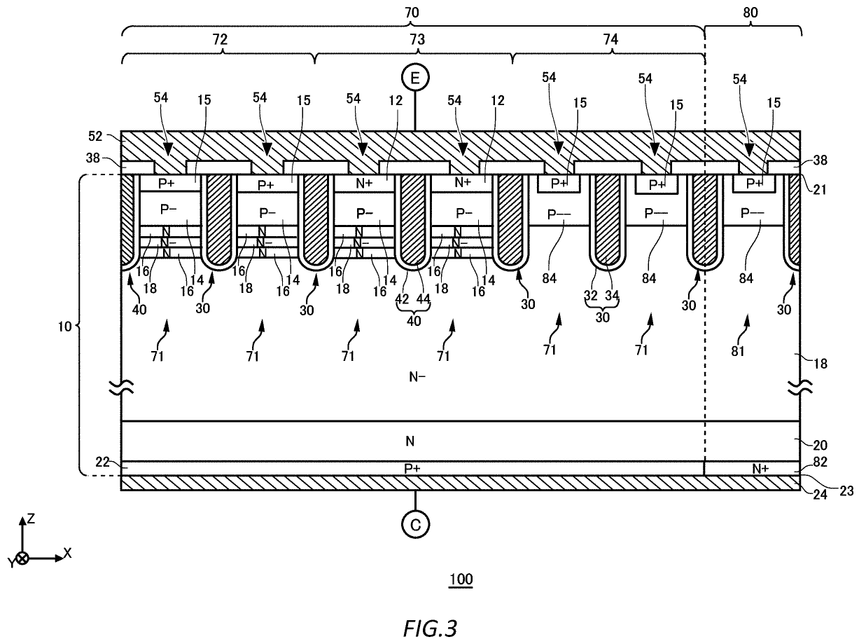

FIG. 3 is a view showing an example of a cross section a-a′ in FIG. 2. The cross section a-a′ is an XZ plane passing through the contact region 15 in the transistor portion 70. The semiconductor device 100 of the present example has the semiconductor substrate 10, the interlayer dielectric film 38, the contact region 15, and a collector electrode 24, in the cross section a-a′. The emitter electrode 52 is formed above the semiconductor substrate 10 and the interlayer dielectric film 38.

The drift region 18 is a region provided in the semiconductor substrate 10. The drift region 18 of the present example is of an N− type as an example. The drift region 18 may be a remaining region where another doping region is not formed in the semiconductor substrate 10. That is, the doping concentration of the drift region 18 may be the doping concentration of the semiconductor substrate 10.

A buffer region 20 is a region provided below the drift region 18. The buffer region 20 of the present example may be of the same conductivity type as that of the drift region 18, and is of the N type as an example. The doping concentration of the buffer region 20 is higher than the doping concentration of the drift region 18. The buffer region 20 may function as a field stop layer to prevent a depletion layer expanding from lower surface sides of the first base region 14 and the second base region 84, from reaching the collector region 22 and the cathode region 82.

The collector region 22 is a region which is provided below the buffer region 20 in the transistor portion 70 and which is of a conductivity type different from that of the drift region 18. The cathode region 82 is a region which is provided below the buffer region 20 in the diode portion and which is of the same conductivity type as that of the drift region 18. A boundary between the collector region 22 and the cathode region 82 is a boundary between the transistor portion 70 and the diode portion 80.

The collector electrode 24 is formed on a back surface 23 of the semiconductor substrate 10. The collector electrode 24 is formed of a conductive material such as metal, or by stacking conductive materials such as the metal.

The first base region 14 is a region which is provided above the drift region 18 in the mesa portions 71 of the first transistor region 72 and the second transistor region 73 and which is of a conductivity type different from that of the drift region 18. The second base region 84 is a region which is provided above the drift region 18 in the mesa portion 71 of the boundary region 74 and the mesa portion 81 and which is of a conductivity type different from that of the drift region 18. The first base region 14 of the present example is of the P− type as an example. In addition, the second base region 84 of the present example is of the P−− type as an example. The doping concentration of the second base region 84 is lower than the doping concentration of the first base region 14. The first base region 14 is provided in contact with the gate trench portion 40. The first base region 14 may be provided in contact with the dummy trench portion 30. On the other hand, the second base region 84 of the present example is provided in contact with the dummy trench portion 30, and is not in contact with the gate trench portion 40.

The emitter region 12 is provided between the first base region 14 and the front surface 21 of the semiconductor substrate 10. In another cross section, the emitter region 12 may be provided at the front surface of the mesa portion 71 in the first transistor region 72 and the second transistor region 73. The emitter region 12 of the present example is not provided in the mesa portion 71 of the boundary region 74 and the mesa portion 81. The emitter region 12 is provided in contact with the gate trench portion 40. The emitter region 12 may be, or may not be in contact with the dummy trench portion 30.

An accumulation region 16 is a region provided to be closer to a front surface 21 side of the semiconductor substrate 10 than the drift region 18. The accumulation region 16 of the present example is of the same conductivity type as that of the drift region 18, and is of the N type as an example. The accumulation region 16 is provided in the transistor portion 70. The accumulation region 16 in the present example is provided in the first transistor region 72 and the second transistor region 73, but is not provided in the boundary region 74. The accumulation region 16 may be provided in the boundary region 74 and the diode portion.

In addition, the accumulation region 16 is provided in contact with the gate trench portion 40. The accumulation region 16 may be, or may not be in contact with the dummy trench portion 30. The doping concentration of the accumulation region 16 is higher than the doping concentration of the drift region 18. Providing the accumulation region 16 makes it possible to enhance a carrier injection enhancement effect (IE effect) to reduce an ON voltage of the transistor portion 70.

In the present example, the accumulation region 16 of a first stage is provided under the first base region 14, and the accumulation region 16 of a second stage is further provided across the drift region 18 provided under the accumulation region 16 of a first stage. The number of stages of the accumulation regions 16 may be appropriately changed according to a desired carrier injection enhancement effect.

One or more gate trench portions 40 and one or more dummy trench portions 30 are provided at the front surface 21 of the semiconductor substrate 10. Each trench portion is provided from the front surface 21 to the drift region 18. In a region provided with at least any of the emitter region 12, the first base region 14, the second base region 84, the contact region 15, and the accumulation region 16, each trench portion also passes through these regions to reach the drift region 18. A structure in which the trench portion passes through the doping region is not limited to a structure in which the semiconductor substrate is manufactured in order of forming the doping region and then forming the trench portion. A structure in which the trench portion is formed and then the doping region is formed between the trench portions is also included in the structure in which the trench portion passes through the doping region.

The gate trench portion 40 has a gate trench, a gate dielectric film 42, and the gate conductive portion 44 that are provided at the front surface 21 of the semiconductor substrate 10. The gate dielectric film 42 is provided to cover an inner wall of the gate trench. The gate dielectric film 42 may be formed by oxidizing or nitriding a semiconductor on the inner wall of the gate trench. The gate conductive portion 44 is provided on an inner side further than the gate dielectric film 42 in the gate trench. The gate dielectric film 42 insulates the gate conductive portion 44 from the semiconductor substrate 10. The gate conductive portion 44 is formed of a conductive material such as polysilicon. The gate trench portion 40 is covered by the interlayer dielectric film 38 at the front surface 21 of the semiconductor substrate 10.

The gate conductive portion 44 includes a region facing the first base region 14 that is adjacent on a mesa portion 71 side with the gate dielectric film 42 interposed therebetween in the depth direction of the semiconductor substrate 10. When a predetermined voltage is applied to the gate conductive portion 44, a channel is formed by an inversion layer of electrons on a surface layer in the first base region 14 at an interface in contact with the gate trench.

The dummy trench portion 30 may have the same structure as that of the gate trench portion 40. The dummy trench portion 30 includes a dummy trench, a dummy dielectric film 32, and the dummy conductive portion 34 that are formed in the front surface 21 side of the semiconductor substrate 10. The dummy dielectric film 32 is provided to cover an inner wall of the dummy trench. The dummy conductive portion 34 is provided in the dummy trench, and is provided on an inner side further than the dummy dielectric film 32. The dummy dielectric film 32 insulates the dummy conductive portion 34 from the semiconductor substrate 10. The dummy trench portion 30 is covered by the interlayer dielectric film 38 at the front surface 21.

The interlayer dielectric film 38 is provided on the front surface 21 of the semiconductor substrate 10. The emitter electrode 52 is provided above the interlayer dielectric film 38. The interlayer dielectric film 38 is provided with one or more contact holes 54 to electrically connect the emitter electrode 52 and the semiconductor substrate 10. Similarly, the contact hole 55 and the contact hole 56 may also be provided to pass through the interlayer dielectric film 38.

It should be noted that as a technique for promoting a carrier annihilation and reducing the reverse recovery loss at a time of the turn-off, it is known that a lifetime control region including a lifetime killer is provided in the drift region 18. The lifetime killer is a crystal defect that is formed at a predetermined depth position in the semiconductor substrate, for example, by implanting helium ions, hydrogen ions (protons), deuterium ions, or the like. The lifetime control region promotes a recombination of a hole generated in the base region when the diode portion is turned off and an electron that is injected from the cathode region, and suppresses a peak current at a time of a reverse recovery.

In the front surface 21 side of the semiconductor substrate 10, the lifetime control region may be provided continuously from the diode portion 80 to at least a part of the boundary region 74. When the diode portion conducts electrocity, the hole current is generated toward the cathode region 82 not only from the second base region 84 of the diode portion 80 but also from the first base region 14 of the transistor portion 70; however, in a manner described above, a lifetime control region 85 provided in the boundary region 74 promotes the carrier annihilation and reduces the reverse recovery loss at the time of the turn-off. The lifetime control region 85 may be provided to have a plurality of peaks of concentration distributions of the lifetime killer in the Z axis direction.

Here, an example of an impurity implantation step for the semiconductor device 100 according to the present example will be described. In the semiconductor substrate 10, the impurities for forming the accumulation region 16 are implanted, by using a mask, into regions forming the first transistor region 72 and the second transistor region 73, and then the impurities for forming the second base region 84 are implanted into the entire surface. Then, the impurities for forming the first base region 14 are implanted, by using the mask, into the regions forming the first transistor region 72 and the second transistor region 73. After that, a plurality of trench portions are formed, by etching, at the front surface 21 of the semiconductor substrate 10.

Then, the impurities for forming the emitter region 12 are implanted, by using the mask, into the regions forming the first transistor region 72 and the second transistor region 73. Then, the impurities for forming the contact region 15 are implanted, by using the mask, into regions forming the first transistor region 72 and the second transistor region 73, and are implanted into the boundary region 74 and the diode portion 80 by using a different mask. After that, at the front surface 21 of the semiconductor substrate 10, a front surface metal layer of the interlayer dielectric film 38, the emitter electrode 52, or the like is formed.

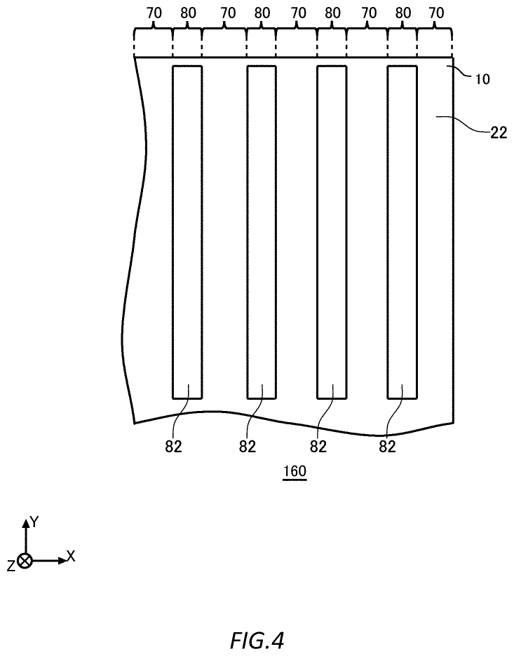

FIG. 4 shows an example of a bottom plan view of the semiconductor device 100. Here, only a part of the active region 160 on the back surface 23 of the semiconductor substrate 10, is shown, and the edge termination structure portion 162 is omitted. The collector electrode 24 provided on the back surface 23 of the semiconductor substrate 10 is also omitted.

The collector region 22 is a region which is provided below the buffer region 20 in the transistor portion 70 and which is of a conductivity type different from that of the drift region 18. The cathode region 82 is a region which is provided below the buffer region 20 in the diode portion 80 and which is of the same conductivity type as that of the drift region 18. A boundary between the collector region 22 and the cathode region 82 is a boundary between the transistor portion 70 and the diode portion 80. In the extension direction, the collector region 22 may be provided between an end portion of the active region 160 and an end portion of the cathode region 82.

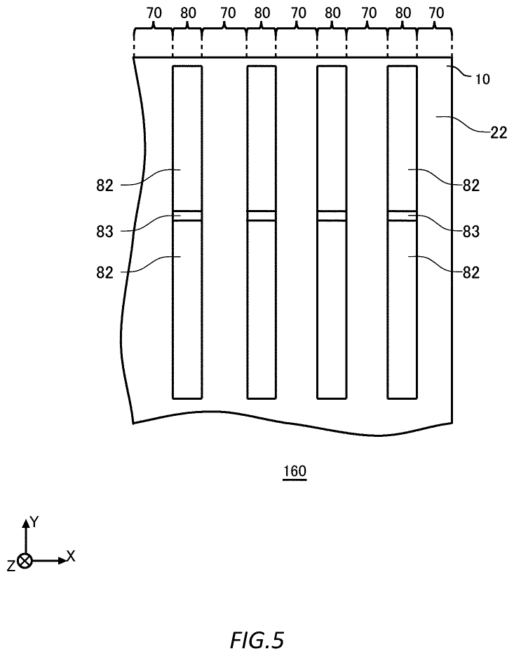

FIG. 5 shows another example of the bottom plan view of the semiconductor device 100. Here, the description common to FIG. 4 is omitted. The cathode region of the present example has the first cathode region 82 of the first conductivity type corresponding to the cathode region 82 of FIG. 4, and a second cathode region 83 which is of the second conductivity type and which has an area smaller than that of the first cathode region 82.

As an example, the second cathode region 83 is a region evenly provided in a part of the first cathode region 82. The second cathode region 83 of the present example may be provided to extend in the array direction. In the extension direction, the first cathode region 82 is longer than the second cathode region 83. The second cathode region 83 may have the same doping concentration as that of the collector region 22. The second cathode region 83 may be in contact with the collector region 22 at an end portion in the array direction. The second cathode region 83 suppresses a surge voltage during the reverse recovery, and improves a characteristic of the diode portion 80.

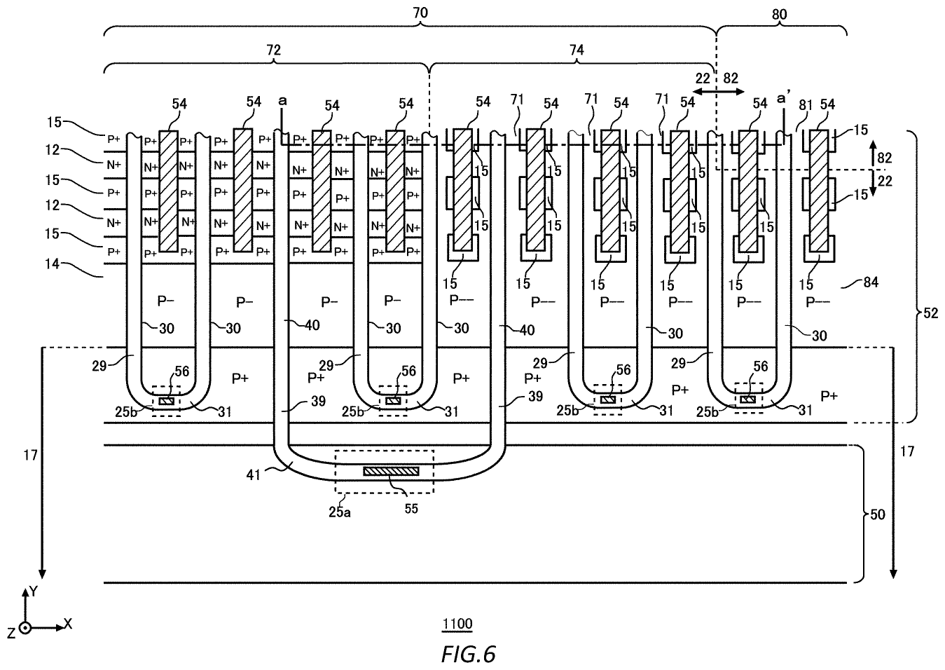

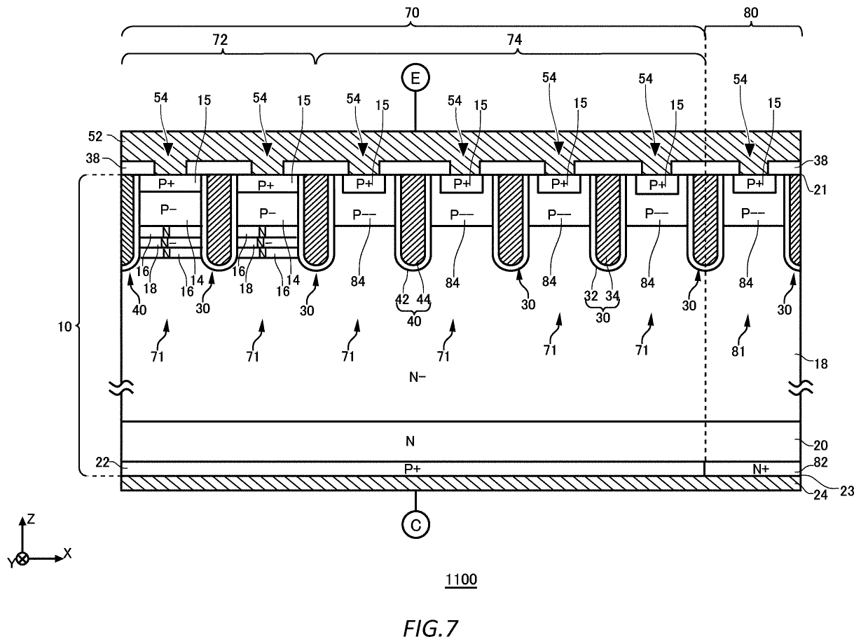

FIG. 6 shows an example of an enlarged view of an upper surface of a semiconductor device 1100 according to a comparison example. FIG. 7 is a view showing an example of a cross section a-a′ in FIG. 6. Here, the description of a member common to that in FIG. 2 is omitted, and the description will focus mainly on a difference.

The transistor portion 70 of the semiconductor device 1100 according to the comparison example has the first transistor region 72 and the boundary region 74; however, unlike the transistor portion 70 of the semiconductor device 100, the second transistor region 73 is not provided between the first transistor region 72 and the boundary region 74.

In the array direction (the X axis direction), the width of the boundary region 74 in the semiconductor device 1100 is narrower than a sum of widths of the second transistor region 73 and the boundary region 74 in the semiconductor device 100. In addition, the width of the boundary region 74 in the semiconductor device 1100 is wider than the width of the boundary region 74 in the semiconductor device 100.

That is, in the semiconductor device 1100, a distance between the first transistor region 72 and the diode portion 80 is shorter than in the semiconductor device 100. Therefore, when the diode portion 80 conducts electrocity, the hole current is generated toward the cathode region 82 from the first base region 14 of the first transistor region 72, to increase the hole density in the semiconductor substrate 10, and thus it takes time for the hole to annihilate along with the turn off of the diode portion 80. Therefore, the semiconductor device 1100 has a greater peak current at the time of the reverse recovery and a greater reverse recovery loss than those of the semiconductor device 100.

In the semiconductor device 100, by the second transistor region 73 having the contact region 15 that has an area smaller than that of the first transistor region 72, being provided between the first transistor region 72 and the boundary region 74, the hole current toward the cathode region 82 is reduced when the diode portion 80 conducts electrocity. Therefore, in the semiconductor device 100, the peak current during the reverse recovery is smaller than in the semiconductor device 1100, and the reverse recovery loss can be reduced.

In addition, the width of the boundary region 74 in the semiconductor device 100 is shorter than the width of the boundary region 74 in the semiconductor device 1100, and instead of this, the second transistor region 73 is provided, and thus it is possible to reduce an ineffective region which does not contribute to a transistor operation.

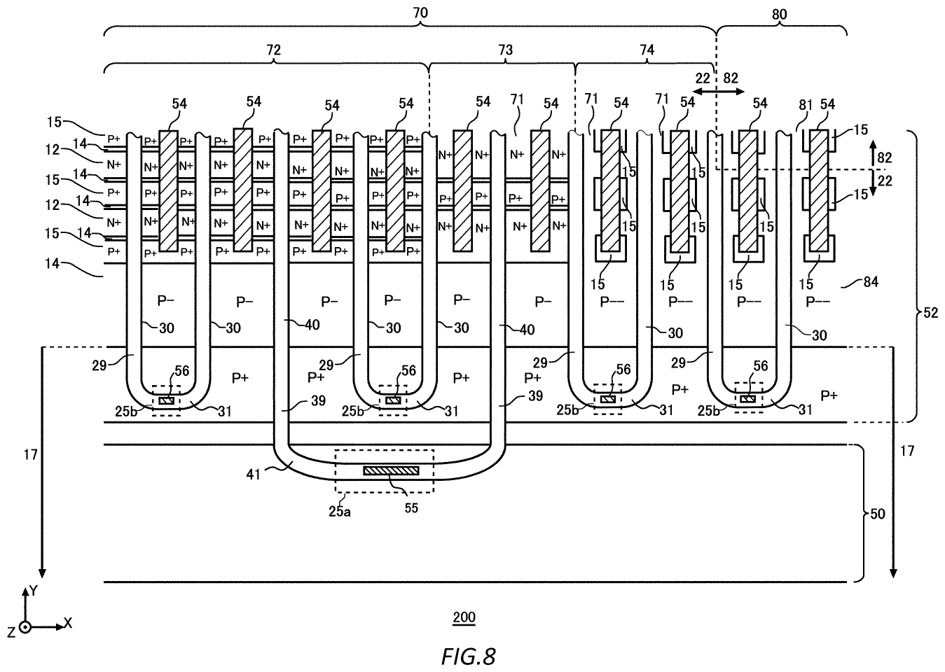

FIG. 8 shows an example of a top plan view of a semiconductor device 200 according to example embodiment 2. Here, the description of a configuration common to that of the semiconductor device 100 shown in FIG. 2 is omitted, and the description will focus mainly on a difference.

In the first transistor region 72 and the second transistor region 73 of the present example, the first base region 14 is exposed to the front surface 21 of the semiconductor substrate 10. In the first transistor region 72 and the second transistor region 73 of the present example, the contact region 15 is interposed between the first base regions 14 in the extension direction (the Y axis direction) at the front surface 21 of the semiconductor substrate 10. That is, in the present example, the first base region 14 is exposed between the emitter region 12 and the contact region 15 at the front surface 21 of the semiconductor substrate 10.

In an example of a formation process of the first transistor region 72 and the second transistor region 73, after the first base region 14 is formed in the semiconductor substrate 10, the emitter region 12 is formed at the front surface 21 of the semiconductor substrate 10, and then the contact region 15 is formed. The first base region 14 that is exposed at the front surface 21 of the semiconductor substrate 10 may be a region where the impurities implanted to form the contact region 15 remain without being diffused to an end portion of the emitter region 12. It should be noted that the emitter region 12 and the contact region 15 may be formed in reverse order.

As described above, by providing the second transistor region 73 between the first transistor region 72 and the boundary region 74, the semiconductor device 200 according to example embodiment 2 also can reduce the reverse recovery loss to obtain an effect similar to that of the semiconductor device 100 according to example embodiment 1.

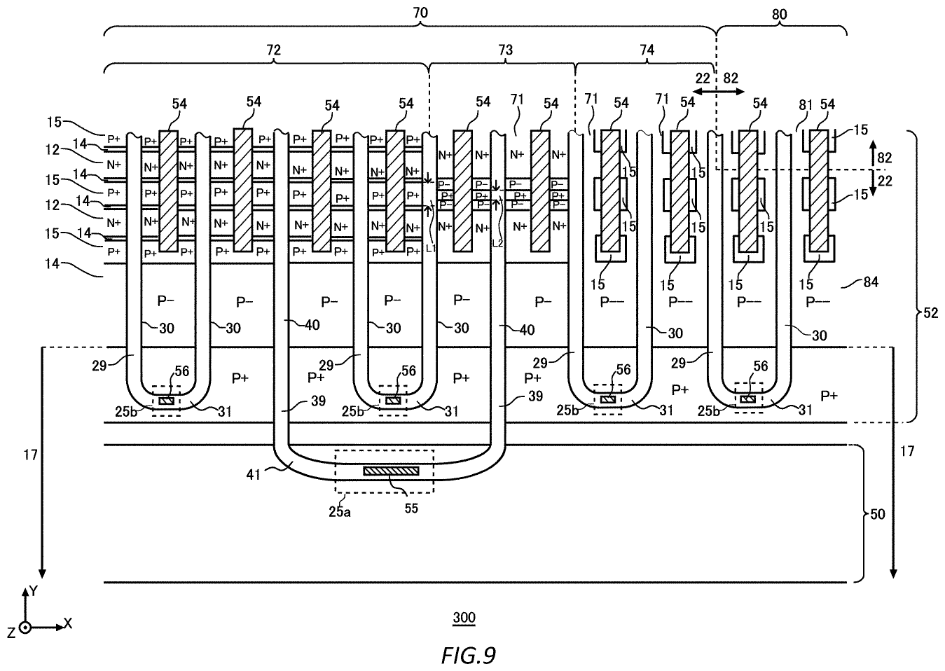

FIG. 9 shows an example of a top plan view of a semiconductor device 300 according to example embodiment 3. Here, the description of a configuration common to the semiconductor device 200 shown in FIG. 8 is omitted, and the description will focus mainly on a difference.

A length L2, in the extension direction (the Y axis direction), of the contact region 15 in the second transistor region 73 of the present example is shorter than a length L1, in the extension direction (the Y axis direction), of the contact region 15 in the first transistor region 72 that is aligned in the array direction (the X axis direction).

That is, in the present example, an area ratio of the contact region 15 in the second transistor region 73 is further made to be smaller, it is possible to further reduce the reverse recovery loss.

In addition, as described in example embodiment 2, in an example of the formation process of the first transistor region 72 and the second transistor region 73, after the first base region 14 is formed in the semiconductor substrate 10, the emitter region 12 is formed at the front surface 21 of the semiconductor substrate 10, and then the contact region 15 is formed. In the present example, the length L2 of the contact region 15 in the extension direction (the Y axis direction) is short, and thus even when a mask position is deviated at a time of an impurity implantation, diffusing into a range of the emitter region 12 is difficult, and it is possible to form the contact region 15 at a predetermined length in the extension direction (the Y axis direction).

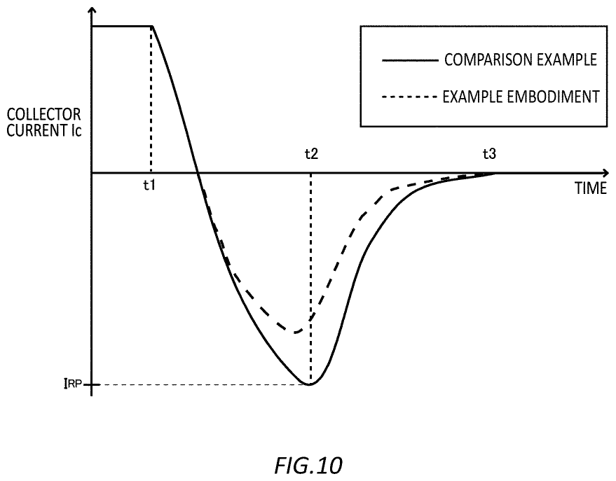

FIG. 10 is a graph showing a temporal change in collector current Ic at a time of a reverse recovery. In the graph of FIG. 10, a solid line indicates the collector current Ic in the semiconductor device (for example, the semiconductor device 1100) according to the comparison example that does not have the second transistor region 73, and a dashed line indicates a behavior of the collector current Ic in the semiconductor device (for example, any of the semiconductor device 100, the semiconductor device 200, and the semiconductor device 300) according to the example embodiment that has the second transistor region 73.

When the transistor portion is turned off at a time t1 and the diode portion 80 conducts electrocity, the electron current flows from the cathode region 82 to the second base region 84 which is operated as the anode layer, and the reverse recovery current is generated. When the electron current reaches the second base region 84, the conductivity modulation occurs, and the hole current flows from the anode layer. Furthermore, the electron current is also diffused from the cathode region 82 to the first base region 14 of the transistor portion 70.

The electron current which is diffused toward the transistor portion 70 promotes the hole injection from the contact region 15 having a doping concentration higher than that of the first base region 14, and increases the hole density in the semiconductor substrate 10, and thus it takes time for the hole to annihilate along with the turn off of the diode portion 80. Therefore, a peak reverse recovery current Irp increases and the reverse recovery loss becomes greater.

Here, the collector current Ic in the semiconductor device according to the comparison example gradually decreases after reaching the peak reverse recovery current Irp at a time t2, and becomes approximately zero around a time t3. When the peak reverse recovery current Irp is great, it takes time for the current to become zero, and thus heat generation increases and the reverse recovery loss increases.

On the other hand, the semiconductor device 100 according to the example embodiment has the second transistor region 73 between the first transistor region 72 and the boundary region 74 of the transistor portion 70.

By the second transistor region 73 and the boundary region 74 being interposed between the first transistor region 72 and the diode portion 80, the distance between the first transistor region 72 and the diode portion 80 is long, and the hole injection from the first transistor region 72 to diode portion 80 is suppressed. In this way, in the semiconductor device according to the example embodiment, the peak reverse recovery current Irp is smaller, and the time it takes for the current to become zero is shorter, than those in the semiconductor device according to the comparison example, and thus the reverse recovery loss is reduced.

While the embodiments of the present invention have been described, the technical scope of the invention is not limited to the above described embodiments. It is apparent to persons skilled in the art that various alterations and improvements can be added to the above-described embodiments. It is also apparent from the description of the claims that the embodiments to which such alterations or improvements are made can be included in the technical scope of the present invention.

The operations, procedures, steps, and stages of each process performed by an apparatus, system, program, and method shown in the claims, specification, or drawings can be performed in any order as long as the order is not indicated by “prior to,” “before,” or the like and as long as the output from a previous process is not used in a later process. Even if the process flow is described using phrases such as “first” or “next” in the claims, specification, or drawings, it does not necessarily mean that the process must be performed in this order.

### EXPLANATION OF REFERENCES

10 . . . semiconductor substrate, 12 . . . emitter region, 14 . . . first base region, 15 . . . contact region, 16 . . . accumulation region, 17 . . . well region, 18 . . . drift region, 20 . . . buffer region, 21 . . . front surface, 22 . . . collector region, 23 . . . back surface, 24 . . . collector electrode, 25a . . . connection portion, 25b . . . connection portion, 29 . . . extension part, 30 . . . dummy trench portion, 31 . . . connection part, 32 . . . dummy dielectric film, 34 . . . dummy conductive portion, 38 . . . interlayer dielectric film, 39 . . . extension part, 40 . . . gate trench portion, 41 . . . connection part, 42 . . . gate dielectric film, 44 . . . gate conductive portion, 50 . . . gate wiring layer, 52 . . . emitter electrode, 54 . . . contact hole, 55 . . . contact hole, 56 . . . contact hole, 70 . . . transistor portion, 71 . . . mesa portion, 72 . . . first transistor region, 73 . . . second transistor region, 74 . . . boundary region, 80 . . . diode portion, 81 . . . mesa portion, 82 . . . cathode region, 83 . . . second cathode region, 84 . . . second base region, 100 . . . semiconductor device, 160 . . . active region, 162 . . . edge termination structure portion, 163 . . . pad region, 200 . . . semiconductor device, 300 . . . semiconductor device, 1100 . . . semiconductor device.

What is claimed is:

1. A semiconductor device comprising a semiconductor substrate that has a transistor portion and a diode portion and that is provided with a plurality of trench portions, wherein
the semiconductor substrate has:
a drift region of a first conductivity type;
a first base region of a second conductivity type provided above the drift region;
a second base region of the second conductivity type which is provided above the drift region and which has a doping concentration lower than that of the first base region;
an emitter region of the first conductivity type which is provided above the first base region and which has a doping concentration higher than that of the drift region; and
a contact region of the second conductivity type which is provided above the first base region and the second base region and which has a doping concentration higher than that of the first base region,
the transistor portion has:
a first transistor region provided with the emitter region, the contact region, and the first base region;
a second transistor region which is provided with the emitter region and the contact region and which is provided between the first transistor region and the diode portion; and
a boundary region which includes the second base region and which is provided between the second transistor region and the diode portion, and
at a front surface of the semiconductor substrate, an area of the contact region in the second transistor region is smaller than an area of the contact region in the first transistor region.

2. The semiconductor device according to claim 1, wherein
in the first transistor region, the first base region is not exposed to the front surface of the semiconductor substrate.

3. The semiconductor device according to claim 1, wherein
in the first transistor region, the first base region is exposed to the front surface of the semiconductor substrate.

4. The semiconductor device according to claim 3, wherein
the contact region is interposed between first base regions, each first base region being identical to the first base region, at the front surface of the semiconductor substrate in the first transistor region.

5. The semiconductor device according to claim 1, wherein
a length, in a trench extension direction, of the contact region in the second transistor region is shorter than a length, in the trench extension direction, of the contact region in the first transistor region that is aligned with the contact region in the second transistor region in a trench array direction.

6. The semiconductor device according to claim 1, wherein
the first base region is provided in the first transistor region and the second transistor region, and
the second base region is provided in the boundary region and the diode portion.

7. The semiconductor device according to claim 1, wherein
a width of the second transistor region is narrower than a width of the boundary region, in a trench array direction.

8. The semiconductor device according to claim 1, wherein
the semiconductor substrate has an accumulation region of the first conductivity type which has a doping concentration higher than that of the drift region.

9. The semiconductor device according to claim 8, wherein
the accumulation region is provided in the transistor portion.

10. The semiconductor device according to claim 8, wherein
the accumulation region is provided in the second transistor region, but is not provided in the boundary region.

11. The semiconductor device according to claim 1, wherein
the plurality of trench portions have gate trench portions and dummy trench portions, and
the second transistor region is provided with at least one gate trench portion.

12. The semiconductor device according to claim 1, wherein
the boundary region and the diode portion have lifetime control regions that include lifetime killers, in a front surface side of the semiconductor substrate.

13. The semiconductor device according to claim 1, wherein
the diode portion has the contact region and the second base region, and
the contact region is provided to be interposed between second base regions, each second base region being identical to the second base region, in the boundary region and the diode portion.

14. The semiconductor device according to claim 1, wherein
the transistor portion further has a collector region of the second conductivity type provided on a back surface of the semiconductor substrate, and
the diode portion further has:
a first cathode region of the first conductivity type provided on the back surface of the semiconductor substrate; and
a second cathode region of the second conductivity type which is provided on the back surface of the semiconductor substrate and which has an area smaller than that of the first cathode region.
